(19) United States
(12) Patent Application Publication
(10) Pub. No.: US 2026/0326240 A1
(43) Pub. Date: Oct. 22, 2026

(54) APPARATUS FOR MANUFACTURING DISPLAY PANEL, METHOD OF MANUFACTURING DISPLAY PANEL, ELECTRONIC DEVICE, AND METHOD OF MANUFACTURING ELECTRONIC DEVICE

(71) Applicant: Samsung Display Co., LTD., Yongin-si (KR)

(72) Inventors: Akifumi Sangu, Yongin-si (KR); Cheolho Park, Yongin-si (KR); Youngsu Chae, Yongin-si (KR)

(21) Appl. No.: 19/468,458

(22) Filed: Feb. 3, 2026

(30) Foreign Application Priority Data
Feb. 4, 2025 (KR) 10-2025-0014073

(51) Int. Cl. B23K 26/34

(52) U.S. Cl. CPC B23K 26/34

(57) ABSTRACT

An apparatus for manufacturing a display panel includes: a light source, a first optical member configured to cause light emitted from the light source to be incident on a first area, and a second optical member configured to cause light reflected from the first area to be incident on a second area. The apparatus is configured to cause light reflected from the second area to be incident back on the first area.

This application claims priority to Korean Patent Application No. 10-2025-0014073, filed on Feb. 4, 2025, and all the benefits accruing therefrom under 35 U.S.C. § 119, the content of which in its entirety is herein incorporated by reference.

### BACKGROUND

### 1. Field

One or more embodiments relate to an apparatus for manufacturing a display panel and a method of manufacturing a display panel. One or more embodiments relate to an apparatus for manufacturing an electronic device including a display panel and a method of manufacturing the electronic device.

### 2. Description of the Related Art

An electronic device may include a display panel as an element for displaying images or videos. A display panel may display images or videos through pixels provided as display elements. A pixel may include a plurality of sub-pixels. Sub-pixels may include light-emitting elements and sub-pixel circuits connected to the light-emitting elements to drive the light-emitting elements. Light-emitting elements may include light-emitting diodes, for example, organic light-emitting diodes. Sub-pixel circuits may include one or more thin-film transistors and various wirings.

### SUMMARY

A process of manufacturing a display panel or an electronic device may include laser processing. The laser processing may include a process of emitting a laser toward an object to be processed (e.g., a semi-finished product of a display panel). A portion of the laser emitted toward the object to be processed may be emitted to a main processing area, which is a processing target area, and another portion of the laser may be emitted to an auxiliary processing area, which is an area for ensuring a process margin. Various attempts have been made to reduce energy (e.g., power) consumed in the laser processing and to improve the quality (and efficiency) of the laser processing.

Additional aspects will be set forth in part in the description which follows and, in part, will be apparent from the description, or may be learned by practice of the presented embodiments of the disclosure.

According to one or more embodiments, an apparatus for manufacturing a display panel includes a light source, a first optical member configured to cause light emitted from the light source to be incident on a first area, and a second optical member configured to cause light reflected from the first area to be incident on a second area, where the apparatus is configured to cause light reflected from the second area to be incident back on the first area.

In an embodiment, the first optical member may include at least one of a mirror or a lens.

In an embodiment, the first optical member may include the mirror and the lens, and the lens may be disposed between the mirror and the first area.

In an embodiment, the second optical member may include a mirror.

In an embodiment, the second optical member may cause the light reflected from the second area to be incident back on the first area.

In an embodiment, a path of the light incident on the second area by the second optical member and a path of the light reflected from the second area may coincide with each other, while a traveling direction of the light incident on the second area by the second optical member and a traveling direction of the light reflected from the second area are opposite to each other.

In an embodiment, the apparatus may further include a third optical member configured to cause the light reflected from the second area to be incident on the first area.

In an embodiment, a path of the light reflected from the first area and a path of the light incident back on the first area by the second optical member may coincide with each other, while a traveling direction of the light reflected from the first area and a traveling direction of the light incident back on the first area by the second optical member may be opposite to each other.

In an embodiment, the second optical member may be integrally provided with the third optical member.

In an embodiment, the apparatus may further include a fourth optical member disposed on a path of the light incident on the second area.

In an embodiment, the fourth optical member may include a lens.

According to one or more embodiments, a method of manufacturing a display panel includes causing light emitted from a light source to be incident on a first area, causing light reflected from the first area to be incident on a second area, and causing light reflected from the second area to be incident back on the first area.

In an embodiment, the causing of the light emitted from a light source to be incident on the first area may include at least one of adjusting a path of light emitted from a light source by using a mirror, or focusing the light by using a lens.

In an embodiment, the causing of the light reflected from the first area to be incident on the second area may include adjusting a path of the light reflected from the first area by using a mirror.

In an embodiment, the causing of the light reflected from the first area to be incident on the second area and the causing of the light reflected from the second area to be incident back on the first area may be performed by the same optical member.

In an embodiment, a path of the light incident on the second area and a path of the light reflected from the second area may coincide with each other.

In an embodiment, the method may further include focusing the light incident on the second area.

In an embodiment, the method may include laser annealing or laser peeling.

According to one or more embodiments, an electronic device includes a display panel, wherein the display panel is manufactured by a method of manufacturing a display panel, the method including causing light to be incident on a first area; causing light reflected from the first area to be incident on a second area, and causing light reflected from the second area to be incident back on the first area.

In an embodiment, the method may include laser annealing or laser peeling.

According to one or more embodiments, a method of manufacturing an electronic device includes manufacturing a display panel, and coupling the manufactured display panel to a housing, where the manufacturing of the display panel includes causing light emitted from a light source to be incident on a first area, causing light reflected from the first area to be incident on a second area, and causing light reflected from the second area to be incident back on the first area.

In an embodiment, the manufacturing of the display panel may include laser annealing or laser peeling.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1A is a schematic cross-sectional view of an apparatus for manufacturing a display panel, according to an embodiment;

FIG. 1B is a schematic cross-sectional view of an apparatus for manufacturing a display panel, according to an embodiment;

FIG. 2 is a schematic cross-sectional view of an apparatus for manufacturing a display panel, according to an embodiment;

FIG. 3 is a schematic perspective view of an apparatus for manufacturing a display panel, according to an embodiment;

FIG. 4 is a schematic cross-sectional view of an apparatus for manufacturing a display panel, according to an embodiment;

FIG. 5 is a schematic cross-sectional view of an apparatus for manufacturing a display panel, according to an embodiment;

FIG. 6 is a schematic cross-sectional view of an apparatus for manufacturing a display panel, according to an embodiment;

FIG. 7 is a graph showing a profile of a beam according to a position on an object to be processed, according to an embodiment;

FIG. 8 is a graph showing a profile of a beam according to a position on an object to be processed, according to an embodiment;

FIG. 9 is a graph showing a profile of a beam according to a position on an object to be processed, according to an embodiment;

FIG. 10 is a block diagram schematically illustrating a method of manufacturing an electronic device, according to an embodiment;

FIG. 11 is a block diagram of an electronic device according to an embodiment;

FIGS. 12 to 14 are schematic diagrams of electronic devices according to various embodiments;

FIG. 15 is a schematic plan view of an electronic device according to an embodiment; and

FIG. 16 is a cross-sectional view of a display panel according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the present description allows for various changes and numerous embodiments, certain embodiments will be illustrated in the drawings and described in detail in the written description. Effects and features of the disclosure, and methods of achieving them will be clarified with reference to embodiments described below in detail with reference to the drawings. However, the disclosure is not limited to the following embodiments and may be embodied in various forms.

Hereinafter, embodiments will be described in detail with reference to the accompanying drawings. When describing embodiments with reference to the accompanying drawings, the same or corresponding elements are denoted by the same reference numerals, and redundant descriptions thereof are omitted.

It will be understood that although the terms “first,” “second,” “first-1”, “first-2”, etc. may be used herein to describe various elements, these elements should not be limited by these terms. These terms are only used to distinguish one element from another.

The singular forms as used herein are intended to include the plural forms as well unless the context clearly indicates otherwise.

It will be further understood that the terms “include” and/or “comprise” used herein specify the presence of stated features or elements, but do not preclude the presence or addition of one or more other features or elements.

It will be further understood that, when a layer, region, or element is referred to as being “on” another layer, region, or element, it may be directly or indirectly on the other layer, region, or element. That is, for example, intervening layers, regions, or elements may be present.

It will be further understood that when layers, regions, or elements are referred to as being connected to each other, they may be directly connected to each other or indirectly connected to each other with intervening layers, regions, or elements therebetween. For example, when layers, regions, or elements are referred to as being electrically connected to each other, they may be directly electrically connected to each other or indirectly electrically connected to each other with intervening layers, regions, or elements therebetween.

As used herein, the expression “A and/or B” indicates only A, only B, or both A and B. The expression “at least one of A and B” indicates only A, only B, or both A and B.

The terms “in a plan view” as used herein may mean seeing a target portion from above (for example, seeing a target object in a direction perpendicular to an upper surface of a substrate), and the terms “in a cross-sectional view” as used herein may mean seeing a vertically cut cross-section of a target portion from a side.

When a first element “overlaps” a second element, it may mean that the first element is disposed above or below the second element so that at least a portion of the first element overlaps the second element in a plan view.

When a certain embodiment may be implemented differently, a specific process order may be performed differently from the described order. For example, two consecutively described processes may be performed substantially at the same time or performed in an order opposite to the stated order.

Also, sizes of elements in the drawings may be exaggerated or reduced for convenience of explanation. For example, because sizes and thicknesses of elements in the drawings are arbitrarily illustrated for convenience of explanation, the disclosure is not necessarily limited thereto.

The term “path of beam” as used herein may refer to a path along which a peak with the strongest intensity in a beam profile moves. Because beams may have a thickness (or a profile), the beams themselves may overlap (for example, partially) each other even when the paths of beams do not overlap each other. Therefore, it is noted that the expression “the paths of beams do not overlap each other” as used herein does not mean that “the beams do not overlap each other.” Elements indicated by arrows in the drawings and denoted by reference symbols of first to sixth beams L1, L2, L3, L4, L5, and L6 may represent “paths of beams.”

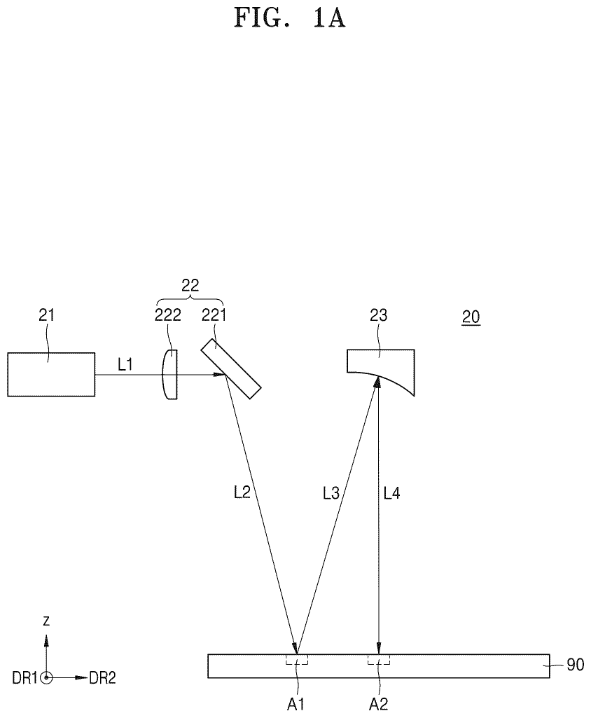

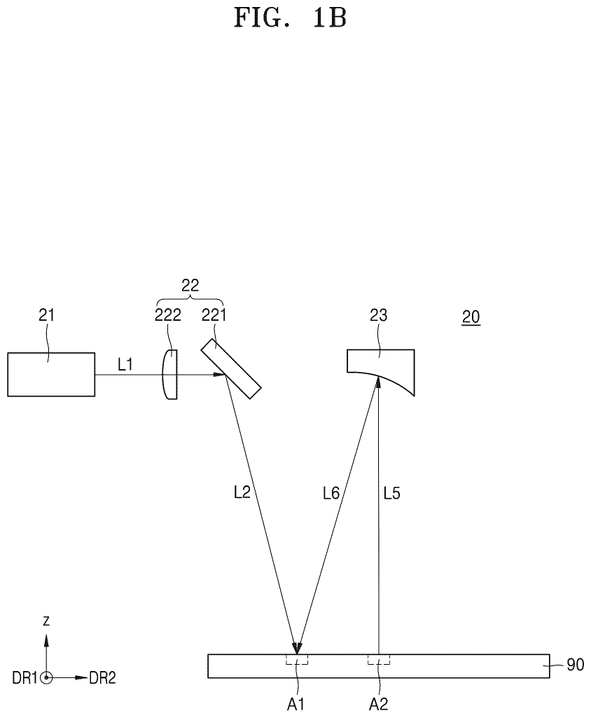

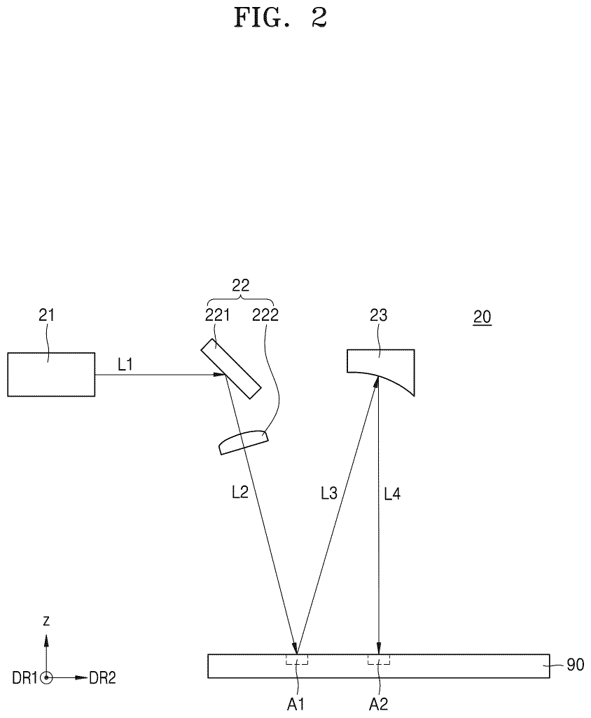

FIG. 1A is a schematic cross-sectional view of an apparatus 20 for manufacturing a display panel, according to an embodiment. FIG. 1B is a schematic cross-sectional view of the apparatus 20 for manufacturing a display panel, according to an embodiment. FIG. 2 is a schematic cross-sectional view of the apparatus 20 for manufacturing a display panel, according to an embodiment.

Referring to FIGS. 1A, 1B, and 2, the apparatus 20 for manufacturing a display panel, according to an embodiment, may be a laser-processing apparatus. An object 90 to be processed is an object to be processed by the apparatus 20 for manufacturing a display panel and may be a semi-finished product of the display panel.

In an embodiment, the object 90 to be processed may include a substrate and an amorphous silicon layer disposed on the upper surface of the substrate. In this case, the apparatus 20 for manufacturing a display panel may be a laser annealing apparatus that converts amorphous silicon into, for example, polysilicon by laser annealing.

In an embodiment, the object 90 to be processed may include a substrate, a plurality of layers disposed on the substrate, and a support supporting the substrate. In this case, the apparatus 20 for manufacturing a display panel may be a laser peeling apparatus that separates the substrate and the plurality of layers from the support.

The examples of the laser-processing apparatus do not limit the disclosure, and any apparatus for performing laser processing on the object 90 to be processed may fall within the scope of the disclosure.

The apparatus 20 for manufacturing a display panel may perform laser processing by emitting a laser beam toward the object 90 to be processed. The laser beam may be emitted to a first area A1 and a second area A2 of the object 90 to be processed. In an embodiment, the first area A1 may be a main processing area in which main laser processing intended by the apparatus 20 for manufacturing a display panel is performed. In an embodiment, the second area A2 may be an auxiliary processing area in which a laser beam is additionally emitted to ensure the process margin of the apparatus 20 for manufacturing a display panel.

The apparatus 20 for manufacturing a display panel may emit a laser beam to the object 90 to be processed along a z direction as a whole. The object 90 to be processed may be moved along a direction crossing a direction in which the laser beam is emitted, for example, along a second direction DR2. Although not illustrated, the apparatus 20 for manufacturing a display panel may include an appropriate component that moves the object 90 to be processed.

FIG. 1A illustrates a first beam L1, a second beam L2, a third beam L3, and a fourth beam L4. FIG. 1B illustrates a first beam L1, a second beam L2, a fifth beam L5, and a sixth beam L6. In an embodiment, the paths of the fourth beam L4 and the fifth beam L5 may coincide with each other, and the paths of the third beam L3 and the sixth beam L6 may coincide with each other. Accordingly, for convenience of illustration and explanation, FIG. 1A illustrates the third beam L3 and the fourth beam L4 and FIG. 1B illustrates the fifth beam L5 and the sixth beam L6.

The apparatus 20 for manufacturing a display panel may include a light source 21, a first optical member 22, and a second optical member 23.

The light source 21 may emit a laser beam in one direction, for example, in the second direction DR2. The laser beam emitted by the light source 21 is referred to as the first beam L1. The first beam L1 may be incident on the first optical member 22. The first optical member 22 may be disposed on the path of the first beam L1.

The first optical member 22 may include a first-1 optical member 221 and a first-2 optical member 222. In an embodiment, the first-1 optical member 221 may include a mirror. In an embodiment, the mirror of the first-1 optical member 221 may be a plane mirror. In an embodiment, the first-2 optical member 222 may include a lens. In an embodiment, the lens of the first-2 optical member 222 may include a convex lens.

The first beam L1 may be light incident on the first-1 optical member 221. The second beam L2 may be light reflected from the first-1 optical member 221. In an embodiment, the first-1 optical member 221 may be disposed on the path of the first beam L1. In an embodiment, the first-1 optical member 221 may be oriented so that the second beam L2 is directed toward the first area A1 of the object 90 to be processed. Alternatively, an area of the object 90 to be processed, where the second beam L2 starting from the first-1 optical member 221 arrives, may be understood as the first area A1.

In an embodiment, as illustrated in FIGS. 1A and 1B, the first-2 optical member 222 may be positioned on the path of the first beam L1. In this case, the first-2 optical member 222 may focus the first beam L1 along a direction (e.g., the z direction) perpendicular to the traveling direction of the first beam L1 (e.g., the second direction DR2).

In another embodiment, as illustrated in FIG. 2, the first-2 optical member 222 may be positioned on the path of the second beam L2. In this case, the first-2 optical member 222 may focus the second beam L2 along a direction perpendicular to the traveling direction of the second beam L2.

The second beam L2 may be light incident on the first area A1 of the object 90 to be processed. The third beam L3 may be light reflected from the first area A1 of the object 90 to be processed. In an embodiment, the surface of the object 90 to be processed, where the second beam L2 is incident, for example, the surface facing the +z direction, may be flat.

The third beam L3 may be light incident on the second optical member 23. The fourth beam L4 may be light reflected from the second optical member 23. In an embodiment, the second optical member 23 may include a mirror. In an embodiment, the mirror of the second optical member 23 may be a curved mirror. In an embodiment, the mirror of the second optical member 23 may be a concave mirror. In another embodiment, the mirror of the second optical member 23 may be a plane mirror. In an embodiment, the second optical member 23 may be disposed on the path of the third beam L3. In an embodiment, the second optical member 23 may be oriented so that the fourth beam L4 is directed toward the second area A2 of the object 90 to be processed. In other words, the second optical member 23 may be provided so that the fourth beam L4 is directed toward the second area A2 of the object 90 to be processed. Alternatively, an area of the object 90 to be processed, where the fourth beam L4 starting from the second optical member 23 arrives, may be understood as the second area A2.

The fourth beam L4 may be light incident on the second area A2 of the object 90 to be processed. The fifth beam L5 may be light reflected from the second area A2 of the object 90 to be processed. In an embodiment, the surface of the object 90 to be processed, where the fourth beam L4 is incident, for example, the surface facing the +z direction, may be flat. In an embodiment, the path of the fourth beam L4 and the path of the fifth beam L5 may overlap each other. In an embodiment, the path of the fourth beam L4 and the path of the fifth beam L5 may coincide with each other, but the traveling direction of the fourth beam L4 and the traveling direction of the fifth beam L5 may be opposite to each other. In an embodiment, the fourth beam L4 may be incident perpendicularly to one surface of the object 90 to be processed, for example, the surface facing the +z direction. In other words, the fourth beam L4 may be incident on the object 90 to be processed, in parallel to a normal direction of the object 90 to be processed. In an embodiment, the fifth beam L5 may be reflected perpendicularly to one surface of the object 90 to be processed, for example, the surface facing the +z direction. In other words, the fifth beam L5 may be reflected from the object 90 to be processed, in parallel to a normal direction of the object 90 to be processed. In an embodiment, the second optical member 23 may be provided so that the fourth beam L4 is incident perpendicularly to the object 90 to be processed and the fifth beam L5 is reflected perpendicularly from the object 90 to be processed.

By disposing the second optical member 23, the second beam L2 may be used for processing the object 90 to be processed in the first area A1, and the reflected light (e.g., the third beam L3) may be used (e.g., recycled) for processing in the second area A2. Accordingly, the efficiency of the apparatus 20 for manufacturing a display panel may be increased by improving the proportion of the laser beam emitted from the light source 21 and used for processing the object 90 to be processed.

The fifth beam L5 may be light incident on the second optical member 23. The sixth beam L6 may be light reflected from the second optical member 23.

In an embodiment, the path of the sixth beam L6 and the path of the third beam L3 may overlap each other. In an embodiment, the path of the sixth beam L6 and the path of the third beam L3 may coincide with each other, but the traveling direction of the sixth beam L6 and the traveling direction of the third beam L3 may be opposite to each other. In an embodiment, the second optical member 23 may be provided so that the sixth beam L6 is directed toward the first area A1 of the object 90 to be processed. In an embodiment, the second optical member 23 may be provided so that the path of the third beam L3 and the path of the sixth beam L6 overlap each other.

The sixth beam L6 may be incident on the first area A1 of the object 90 to be processed. Accordingly, the second beam L2 and the sixth beam L6 may be simultaneously incident on the first area A1 of the object 90 to be processed.

In summary, the apparatus 20 for manufacturing a display panel may cause the second beam L2 to be incident on the first area A1 of the object 90 to be processed, may cause the third beam L3, which is reflected light, to be reflected again so as to be incident on the second area A2 of the object 90 to be processed, as the fourth beam L4, and may cause the fifth beam L5, which is reflected light, to be reflected again to be incident on the first area A1 of the object 90 to be processed, as the sixth beam L6. In other words, the apparatus 20 for manufacturing a display panel may recycle the reflected light (the third beam L3) of the light (the second beam L2), which is provided from the light source 21 and used to process the first area A1 of the object 90 to be processed, as the light (the fourth beam L4) used to process the second area A2 of the object 90 to be processed, and may emit the reflected light (the fifth beam L5) of the light (the fourth beam L4), which is used to process the second area A2, again to the first area A1 so as to be recycled as the light (the sixth beam L6) used to process the first area A1.

Through these processes, the apparatus 20 for manufacturing a display panel may obtain various effects. First, the process margin may be ensured by processing the second area A2. In addition, the second area A2 may be processed without using an additional laser beam. In addition, the beam reflected from the second area A2 may be recycled for processing the first area A1 to increase energy efficiency. In addition, when energy required to process the first area A1 is supplied through the second beam L2 and the sixth beam L6 rather than only through the second beam L2, the amount of initial energy required for the beam emitted from the light source 21 may be reduced, which may lead to a reduction in power consumption of the apparatus 20 for manufacturing a display panel.

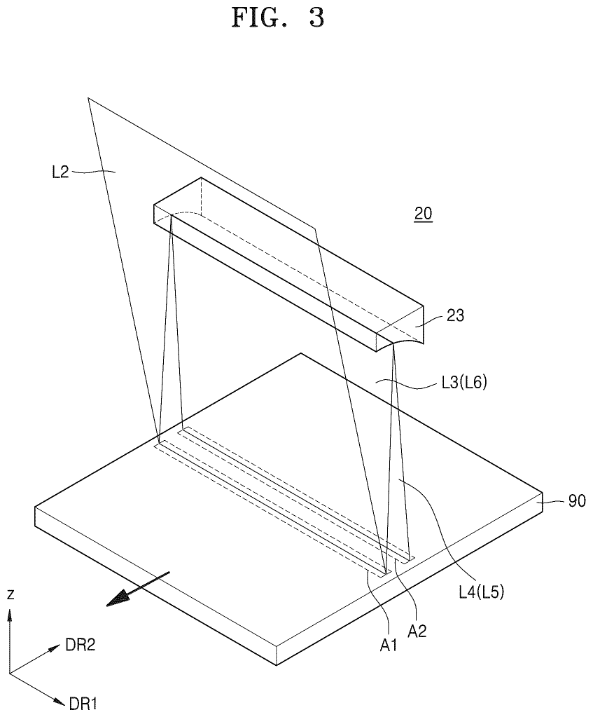

FIG. 3 is a schematic perspective view of a portion of an apparatus 20 for manufacturing a display panel, according to an embodiment. FIG. 3 may correspond to the apparatus 20 for manufacturing a display panel, which is illustrated in FIGS. 1A, 1B, and 2.

Referring to FIG. 3, the second to sixth beams L2 to L6 may be provided as line beams. Although not illustrated, the first beam (see L1 of FIG. 1A) may also be provided as a line beam. FIG. 3 illustrates the third beam L3 and the sixth beam L6 as overlapping each other and the fourth beam L4 and the fifth beam L5 as overlapping each other.

In an embodiment, the second to sixth beams L2 to L6 may be line beams extending along the first direction DR1. In other words, the major axes of the second to sixth beams L2 to L6 may extend in the first direction DR1. In an embodiment, the second to sixth beams L2 to L6 may be line beams having a thickness along the second direction DR2. In other words, the minor axes of the second to sixth beams L2 to L6 may extend in the second direction DR2.

The second optical member 23 may have a shape of a mirror extending along the first direction DR1 to correspond to the shape of the second to sixth beams L2 to L6. The first area A1 may have a shape extending along the first direction DR1 to correspond to the shape of the second beam L2 and the sixth beam L6. The second area A2 may have a shape extending along the first direction DR1 to correspond to the shape of the fourth beam L4 and the fifth beam L5.

The object 90 to be processed may be processed along a direction (e.g., the second direction DR2) crossing a direction (e.g., the first direction DR1) in which the line beams of the second to sixth beams L2 to L6 extend. In an embodiment, the object 90 to be processed may be processed while moving relative to the second direction DR2. In an embodiment, the object 90 to be processed may be laser-processed while the apparatus 20 for manufacturing a display panel is fixed and the object 90 to be processed moves in the second direction DR2 or in a direction opposite to the second direction DR2. In an embodiment, the object 90 to be processed may be laser-processed while the object 90 to be processed is fixed and the apparatus 20 for manufacturing a display panel moves in the second direction DR2 or in a direction opposite to the second direction DR2. FIG. 3 illustrates an embodiment in which the apparatus 20 for manufacturing a display panel is fixed and the object 90 to be processed moves in a direction opposite to the second direction DR2.

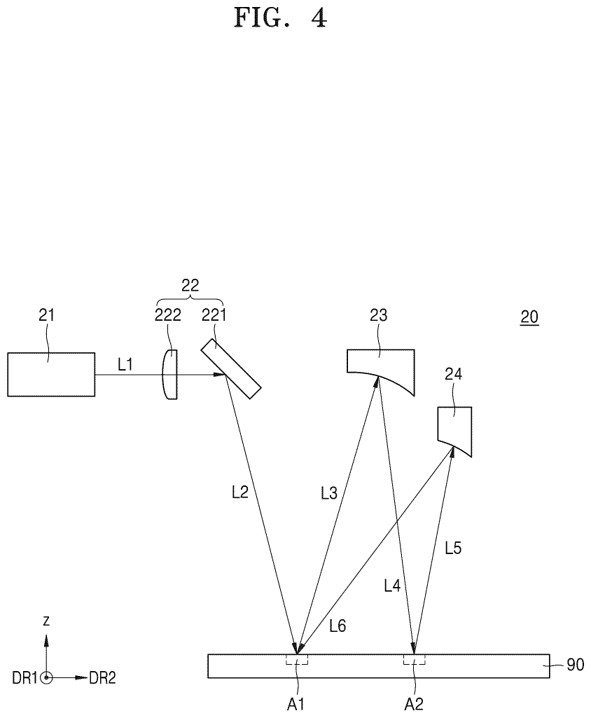

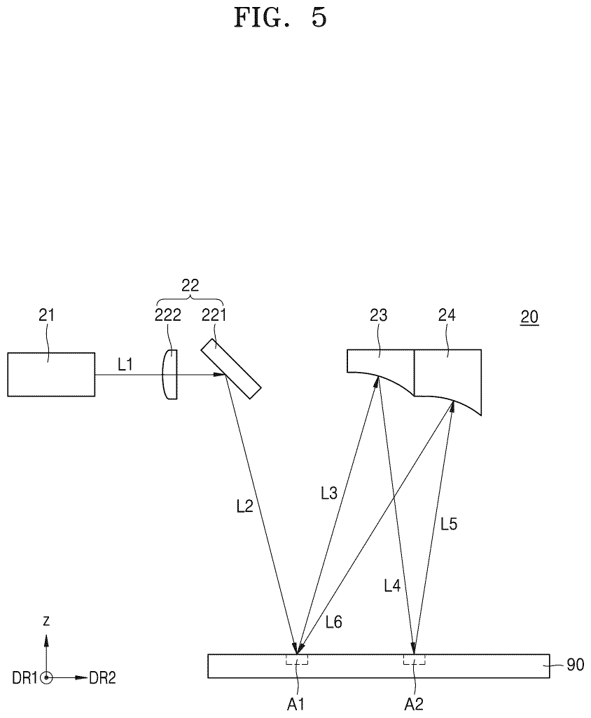

FIG. 4 is a schematic cross-sectional view of an apparatus 20 for manufacturing a display panel, according to an embodiment. FIG. 5 is a schematic cross-sectional view of the apparatus 20 for manufacturing a display panel, according to an embodiment.

Referring to FIGS. 4 and 5, the apparatus 20 for manufacturing a display panel may include a third optical member 24. In an embodiment, the third optical member 24 may include a mirror. In an embodiment, the mirror of the third optical member 24 may be a curved mirror. In an embodiment, the mirror of the third optical member 24 may be a concave mirror. In an embodiment, the mirror of the third optical member 24 may be a plane mirror.

In an embodiment, a path of a fourth beam L4 and a path of a fifth beam L5 may not overlap each other. In other words, a second optical member 23 may be provided so that the fourth beam L4 is incident on a second area A2 of an object 90 to be processed at an angle that is not perpendicular to one surface of the object 90 to be processed (e.g., the surface facing the +z direction). In an embodiment, the position of the second area A2 in the embodiment of FIG. 4 may be different from the position of the second area A2 in the embodiment of FIGS. 1A, 1B, or 2.

A fifth beam L5 may be light incident on the third optical member 24. A sixth beam L6 may be light reflected from the third optical member 24. The sixth beam L6 may be directed toward a first area A1 of the object 90 to be processed. In an embodiment, the third optical member 24 may be disposed on the path of the fifth beam L5. In an embodiment, the third optical member 24 may be oriented so that the sixth beam L6 is directed toward the first area A1 of the object 90 to be processed. In other words, the third optical member 24 may be provided so that the sixth beam L6 is directed toward the first area A1 of the object 90 to be processed.

In an embodiment, as illustrated in FIG. 4, the second optical member 23 and the third optical member 24 may be separately provided. In an embodiment, the second optical member 23 and the third optical member 24 may be individually controlled. In an embodiment, the positions of the first area A1 and the second area A2 may be adjusted by adjusting the positions and orientations of the second optical member 23 and the third optical member 24. In an embodiment, because the second optical member 23 and the third optical member 24 may be individually controlled, the position of the first area A1 and the position of the second area A2 may also be individually adjusted.

In an embodiment, as illustrated in FIG. 5, the second optical member 23 may be integrally provided with the third optical member 24. In an embodiment, the second optical member 23 and the third optical member 24 may be separate mirrors coupled to each other. In an embodiment, the second optical member 23 and the third optical member 24 may be an integral mirror having different reflection surfaces. In an embodiment, the second optical member 23 and the third optical member 24 may be an integral mirror sharing one reflection surface. In an embodiment, because the second optical member 23 may be integrally provided with the third optical member 24, the position of the first area A1 and the position of the second area A2 may be adjusted together. In an embodiment, the position of the first area A1, the position of the second area A2, and the distance between the first area A1 and the second area A2 may be adjusted by adjusting the positions and orientations of the second optical member 23 and the third optical member 24 and the shapes of the reflection surfaces.

The embodiment illustrated in FIG. 4 has an advantage that the positions of the first area A1 and the second area A2 may be independently adjusted because the positions and orientations of the second optical member 23 and the third optical member 24 may be individually adjusted. The embodiment illustrated in FIG. 5 has an advantage that the configuration of the apparatus 20 for manufacturing a display panel may be simplified because the second optical member 23 may be integrally provided with the third optical member 24.

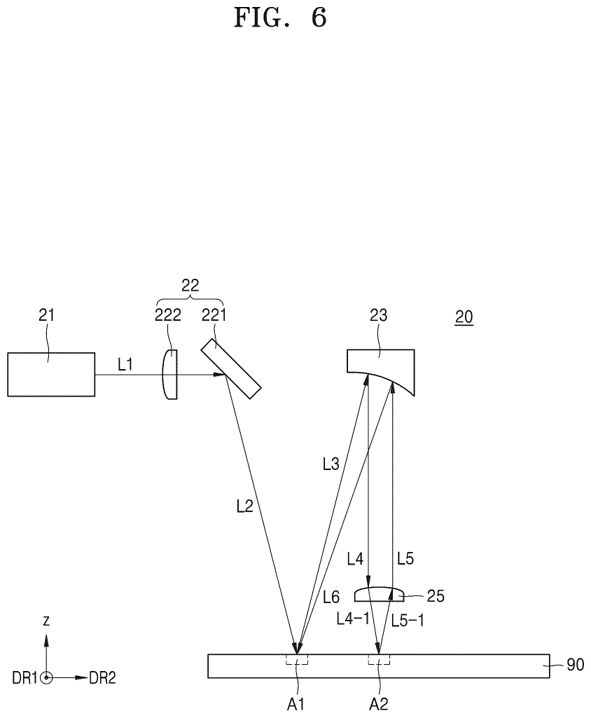

FIG. 6 is a schematic cross-sectional view of an apparatus 20 for manufacturing a display panel, according to an embodiment.

Referring to FIG. 6, the apparatus 20 for manufacturing a display panel may include a fourth optical member 25. In an embodiment, the fourth optical member 25 may include a lens. In an embodiment, the lens of the fourth optical member 25 may include a convex lens.

In an embodiment, the fourth optical member 25 may be provided on a path of a fourth beam L4 and a path of a fifth beam L5. The fourth beam L4 may be refracted and focused while passing through the fourth optical member 25. The beam having passed through the fourth optical member 25 may be defined as a fourth-1 beam L4-1. In an embodiment, the path of the fourth-1 beam L4-1 may be bent in the path of the fourth beam L4. Accordingly, the fourth-1 beam L4-1 may be incident at an angle that is not perpendicular to one surface of an object 90 to be processing (e.g., the surface facing the +z direction). Light of the fourth-1 beam L4-1 reflected from the second area A2 of the object 90 to be processed may be defined as a fifth-1 beam L5-1. The path of the fourth-1 beam L4-1 and the path of the fifth-1 beam L5-1 may not overlap each other. The fifth-1 beam L5-1 may be refracted while passing through the fourth optical member 25. The beam having passed through the fourth optical member 25 may be the fifth beam L5. The path of the fifth beam L5 may be bent from the path of the fifth-1 beam L5-1. Accordingly, the fourth beam L4 and the fifth beam L5 may travel parallel to each other along a direction perpendicular to one surface of the object 90 to be processed, for example, the z direction, and the path of the fourth beam L4 and the path of the fifth beam L5 may not overlap each other. In an embodiment, a point at which the third beam L3 is reflected from the second optical member 23 may be different from a point at which the fifth beam L5 is reflected from the second optical member 23. The second optical member 23 may be provided so that the sixth beam L6 is directed toward the first area A1 of the object 90 to be processed.

By disposing the fourth optical member 25, the density of the beam emitted to the second area A2 may be improved. For example, by focusing the fourth beam L4 through the fourth optical member 25, a beam (e.g., the fourth-1 beam L4-1) having a density that is higher than a density of the fourth beam L4 may be emitted to the second area A2.

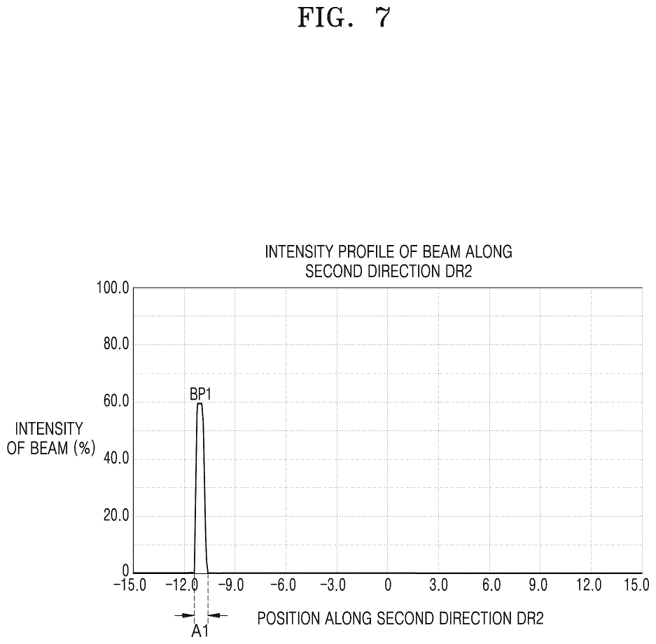

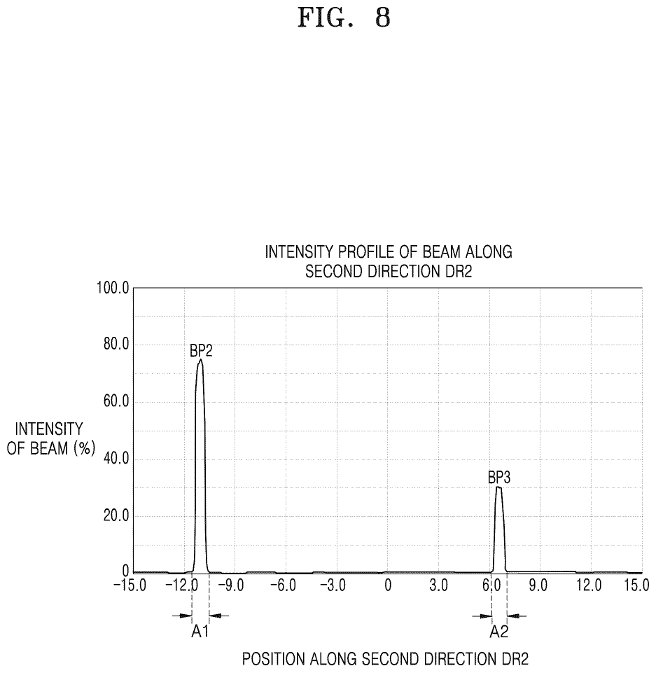

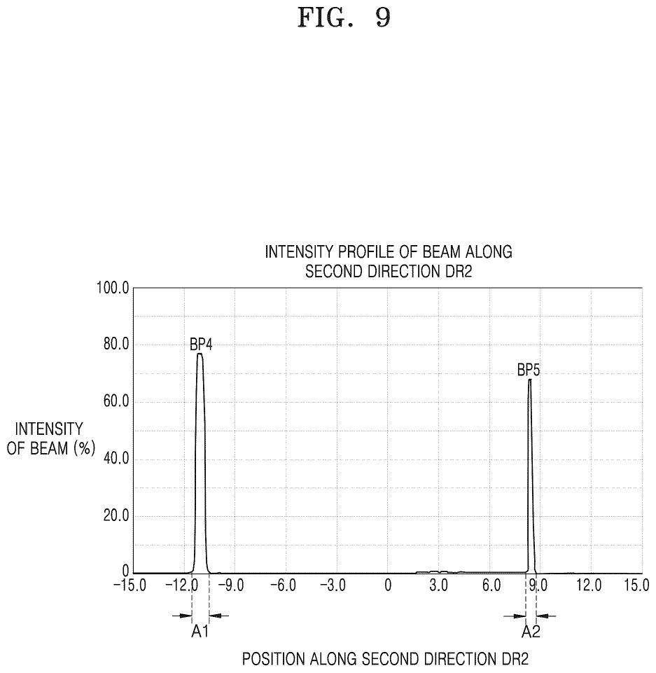

FIG. 7 is a graph showing a profile of a beam according to a position on an object to be processed, according to an embodiment. FIG. 8 is a graph showing a profile of a beam according to a position on an object to be processed, according to an embodiment. FIG. 9 is a graph showing a profile of a beam according to a position on an object to be processed, according to an embodiment.

Referring to FIGS. 7 to 9, the horizontal-axis represents the position on the object 90 to be processed, for example, the position along the second direction DR2, and the vertical-axis represents the intensity of the beam. The unit of the position along the second direction DR2 may be millimeters (mm) or micrometers (μm). The intensity of the beam is a relative value, and the unit of the intensity of the beam is %.

FIG. 7 illustrates a first beam profile BP1 as a comparative example. Referring to FIGS. 1A and 7 together, the first beam profile BP1 may be a profile when only the second beam L2 is emitted to the first area A1 of the object 90 to be processed. In an embodiment, the first beam profile BP1 may have a peak intensity of about 60%.

FIG. 8 illustrates a second beam profile BP2 and a third beam profile BP3. Referring to FIGS. 1A, 1B, and 8 together, the second beam profile BP2 may be a profile when the second beam L2 and the sixth beam L6 are emitted to the first area A1 of the object 90 to be processed. The third beam profile BP3 may be a profile when the fourth beam L4 is emitted to the second area A2 of the object 90 to be processed. In an embodiment, the second beam profile BP2 may have a peak intensity of about 75%. In an embodiment, the third beam profile BP3 may have a peak intensity of about 30%.

Referring to FIGS. 7 and 8, the second beam profile BP2 may have a peak intensity that is higher than a peak intensity of the first beam profile BP1. This is because the first beam profile BP1 is a beam profile when only the second beam L2 is emitted and the second beam profile BP2 is a beam profile when the second beam L2 and the sixth beam L6 are emitted together. Accordingly, the use of the apparatus 20 for manufacturing a display panel, according to the disclosure, may enable a beam profile (e.g., the second beam profile BP2) with a higher intensity than the comparative example (the first beam profile BP1) to be formed in the first area A1 of the object 90 to be processed by using the same light source 21.

FIG. 9 illustrates a fourth beam profile BP4 and a fifth beam profile BP5. FIG. 9 may correspond to the embodiment illustrated in FIG. 6. Referring to FIGS. 6 and 9 together, the fourth beam profile BP4 may be a profile when the second beam L2 and the sixth beam L6 are emitted to the first area A1 of the object 90 to be processed. The fifth beam profile BP5 may be a profile when the fourth-1 beam L4-1 is emitted to the second area A2 of the object 90 to be processed. In an embodiment, the fourth beam profile BP4 may have a peak intensity of about 75%. In an embodiment, the fifth beam profile BP5 may have a peak intensity of about 68%.

Referring to FIGS. 8 and 9, in an embodiment, the fourth beam profile BP4 may be substantially identical to the second beam profile BP2. In an embodiment, the fifth beam profile BP5 may have a peak intensity that is higher than a peak intensity of the third beam profile BP3. In an embodiment, the width of the fifth beam profile BP5 along the second direction DR2 may be narrower than the width of the third beam profile BP3 along the second direction DR2. This is because the third beam profile BP3 may be the profile of the fourth beam L4 and the fifth beam profile BP5 may be the profile of the fourth-1 beam L4-1 in which the fourth beam L4 is focused through the fourth optical member 25.

In other words, the apparatus 20 for manufacturing a display panel, according to an embodiment, may implement a beam profile (e.g., the second beam profile BP2 of FIG. 8 and the fourth beam profile BP4 of FIG. 9) having a higher intensity than when the beam is not recycled (e.g., the first beam profile BP1 of FIG. 7) by emitting the second beam L2 and the recycled beam (e.g., the sixth beam L6) to the first area A1 of the object 90 to be processed. The apparatus 20 for manufacturing a display panel, according to an embodiment, may recycle the beam to implement a beam profile (e.g., the third beam profile BP3 of FIG. 8) of a certain intensity in the second area A2 of the object 90 to be processed. The apparatus 20 for manufacturing a display panel, according to an embodiment, may pass the recycled beam through the lens to implement a beam profile of a higher intensity (e.g., the fifth beam profile BP5 of FIG. 9).

The positions and peak intensities of the beam profiles described above with reference to FIGS. 7 to 9 are only examples and do not limit the disclosure.

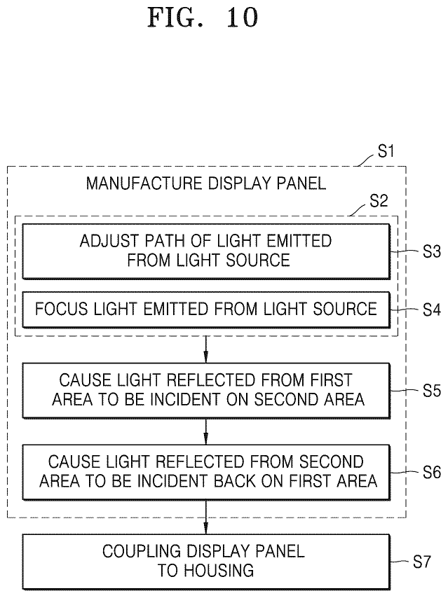

FIG. 10 is a block diagram schematically illustrating a method of manufacturing an electronic device, according to an embodiment.

Referring to FIG. 10, the method of manufacturing an electronic device may include operation S1 of manufacturing a display panel. Operation S1 of manufacturing the display panel may include a method of manufacturing a display panel. The method of manufacturing a display panel may be implemented by the apparatus 20 for manufacturing a display panel, which has been described above with reference to FIGS. 1 to 9. For example, the method of manufacturing a display panel may be implemented by driving the apparatus 20 for manufacturing a display panel, which has been described above. Therefore, the method of manufacturing a display panel may include substantially the same features as the apparatus 20 for manufacturing a display panel, which has been described above. In an embodiment, the method of manufacturing a display panel may include laser annealing or laser peeling.

Referring to FIGS. 1A, 1B, and 10, operation S1 of manufacturing a display panel may include operation S2 of causing light to be incident on the first area A1, operation S5 of causing light reflected from the first area A1 to be incident on the second area A2, and operation S6 of causing light reflected from the second area A2 to be incident back on the first area A1.

Operation S2 of causing the light to be incident on the first area A1 may include operation S3 of adjusting the path of the light emitted from the light source 21 and operation S4 of focusing the light emitted from the light source 21. In an embodiment, the light incident on the first area A1 in operation S2 may be the second beam L2. Operation S3 of adjusting the path of the light emitted from the light source 21 may be performed by the first optical member 22, for example, the first-1 optical member 221. Operation S4 of focusing the light emitted from the light source 21 may be performed by the first optical member 22, for example, the first-2 optical member 222. In an embodiment, the light emitted from the light source 21 in operation S4 may be the first beam L1.

Operation S5 of causing light reflected from the first area A1 to be incident on the second area A2 may be performed by the second optical member 23. In an embodiment, in operation S5, the light reflected from the first area A1 may be the third beam L3, and the light incident on the second area A2 may be the fourth beam L4. In an embodiment, operation S5 of causing the light reflected from the first area A1 to be incident on the second area A2 may include adjusting the path of the light (e.g., the third beam L3) reflected from the first area A1 by the second optical member 23.

Operation S6 of causing light reflected from the second area A2 to be incident back on the first area A1 may be performed by the second optical member 23 (see FIGS. 1B, 2, 3, and 6) or the third optical member 24 (see FIGS. 4 and 5). In an embodiment, in operation S6, the light reflected from the second area A2 may be the fifth beam L5, and the light incident back on the first area A1 may be the sixth beam L6.

In an embodiment, operation S5 of causing the light (e.g., the third beam L3) reflected from the first area A1 to be incident on the second area A2 and operation S6 of causing the light (e.g., the fifth beam L5) reflected from the second area A2 to be incident back on the first area A1 may be performed by the same optical member (e.g., the second optical member 23) (see FIGS. 1A, 1B, 2, and 6).

In an embodiment, the path of the light (e.g., the fourth beam L4) incident on the second area A2 and the path of the light (e.g., the fifth beam L5) reflected from the second area A2 may coincide with each other (see FIGS. 1A, 1B, and 2).

In an embodiment, operation S1 of manufacturing the display panel may include focusing the light incident on the second area A2. The focusing of the light incident on the second area A2 may be performed through the fourth optical member 25 (see FIG. 6).

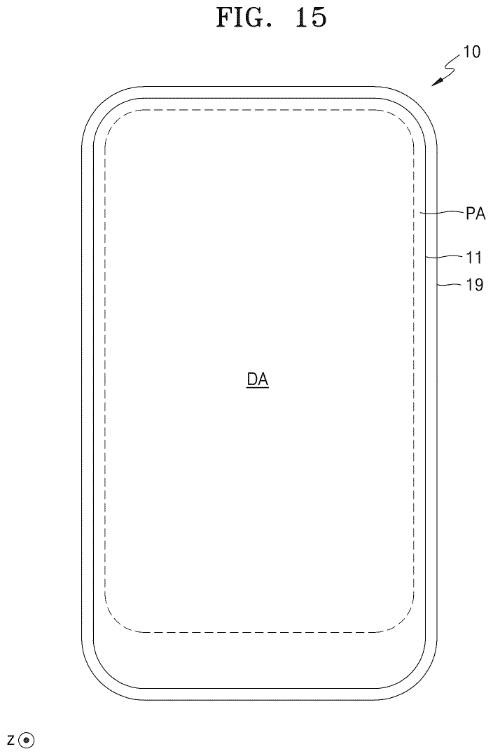

The method of manufacturing an electronic device may include operation S7 of coupling, to a housing 19 (see FIG. 15), the display panel 11 manufactured by the apparatus 20 for manufacturing a display panel or a method of manufacturing a display panel.

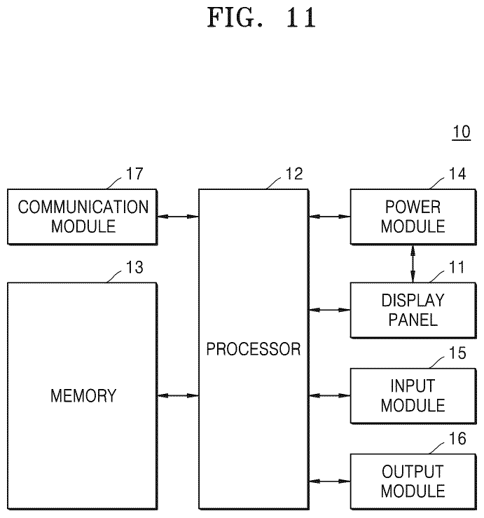

FIG. 11 is a block diagram of an electronic device 10 according to an embodiment.

Referring to FIG. 11, the electronic device 10 may include a display panel 11, a processor 12, a memory 13, and a power module 14. In an embodiment, the display panel 11 may be manufactured by the apparatus 20 for manufacturing a display panel or the method of manufacturing a display panel, which has been described above with reference to FIGS. 1 to 10. In an embodiment, the electronic device 10 may be manufactured by the method of manufacturing an electronic device, which has been described above with reference to FIG. 10.

The processor 12 may include at least one of a central processing unit (CPU), an application processor (AP), a graphics processing unit (GPU), a communication processor (CP), an image signal processor (ISP), or a controller. In an embodiment, the processor 12 may be functionally or structurally divided into two or more parts. For example, the processor 12 may include a main processor in the form of a first driving chip including a CPU and an auxiliary processor in the form of a second driving chip including a controller configured to receive an image signal from the main processor and process the image signal to conform to the interface specifications of the display panel 11.

The memory 13 may include at least one of volatile memory or non-volatile memory. Data information for the operation of the processor 12 or the display panel 11 may be stored in the memory 13. When the processor 12 executes an application stored in the memory 13, an image data signal and/or an input control signal may be transmitted to the display panel 11, and the display panel 11 may process the received signal and output image information on a display screen.

The power module 14 may include a power supply module, such as a power adapter or a battery device, and a power conversion module configured to convert power supplied by the power supply module to generate power for the operation of the electronic device 10. The power conversion by the power conversion module may include direct current (DC)-DC conversion, alternating current (AC)-DC conversion, and DC-AC conversion, but the disclosure is not limited thereto.

The electronic device 10 may further include an input module 15, a non-image output module 16, and/or a communication module 17.

The input module 15 may be configured to provide input information to the processor 12 and/or the display panel 11. The input module 15 may include a physical button, a keyboard, a microphone, and other sensor modules. Examples of the sensor modules may include a touch sensor, a pressure sensor, a distance sensor, a position sensor, a digitizer, a motion recognition sensor, a camera sensor, a light-receiving sensor, a photoelectric conversion sensor, a temperature sensor, and a biometric sensor, such as a blood pressure sensor, a blood sugar sensor, an electrocardiogram sensor, or a heart rate sensor.

The non-image output module 16 may be configured to receive non-image information other than the image transmitted from the processor 12 and provide the non-image information to a user. Examples of the non-image output module 16 may include an acoustic module, a haptic module, a light-emitting module, etc., and may include other functional modules unique to the electronic device (e.g., a cooling module of a refrigerator, etc.).

The communication module 17 may be a module responsible for transmitting and receiving information between the electronic device 10 and an external device and may include a receiver and a transmitter. The communication module 17 may include various wireless communication modules, such as a mobile communication module, a Wi-Fi^{TM} module, or a Bluetooth module, and various wired communication modules.

At least one of the components of the electronic device 10 described above may be included in the display device. Furthermore, some of the individual modules functionally included in a single module may be included in the display device, and others may be provided separately from the display device. For example, the display device may include the display panel 11, and the processor 12, the memory 13, and the power module 14 may be provided in the form of other devices within the electronic device 10 other than the display device. As another example, the power module 14 may be provided within the display device and configured to supply power to the processor 12 and the memory 13 provided within the electronic device 10 other than the display device, but the disclosure is not limited to the above examples.

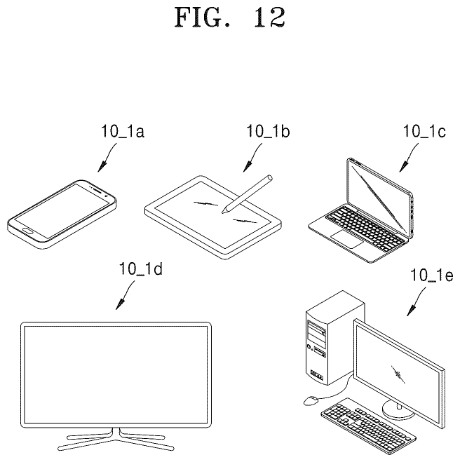

FIGS. 12 to 14 are schematic diagrams of electronic devices according to various embodiments. FIGS. 12 to 14 illustrate examples of various electronic devices to which the display device according to embodiments is applied.

FIG. 12 illustrates examples of the electronic device, including a smartphone 10_1a, a tablet personal computer (PC) 10_1b, a laptop 10_1c, a television (TV) 10_1d, and a desk monitor 10_1e.

The smartphone 10_1a may include, in addition to a display panel, a communication module and an input module, such as a touch sensor. The smartphone 10_1a may be configured to process information received by the communication module or another input module and display the information on the display panel of the display device.

Similar to the smartphone 10_1a, each of the tablet PC 10_1b, the laptop 10_1c, the TV 10_1d, and the desk monitor 10_1e may include a display panel and an input module and, in some cases, may further include a communication module.

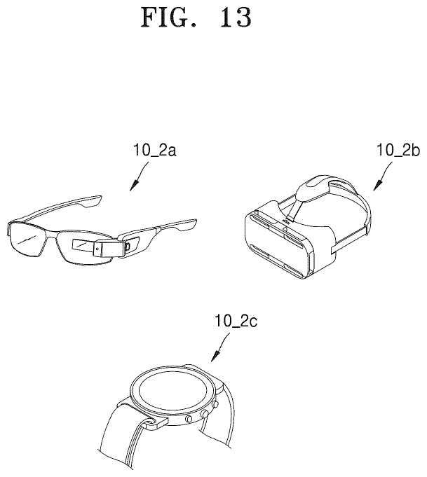

FIG. 13 illustrates examples in which an electronic device including a display panel is applied to a wearable electronic device. The wearable electronic device may be smart glasses 10_2a, a head mounted display 10_2b, a smart watch 10_2c, etc.

Each of the smart glasses 10_2a and the head mounted display 10_2b may include a display panel configured to display a display image and a reflector configured to provide the display image to the user's eyes by reflecting the displayed display image, and may provide a virtual reality or augmented reality screen to the user by the display module and the reflector.

The smart watch 10_2c may include a biometric sensor as an input device and may be configured to provide biometric information recognized by the biometric sensor to the user by the display panel.

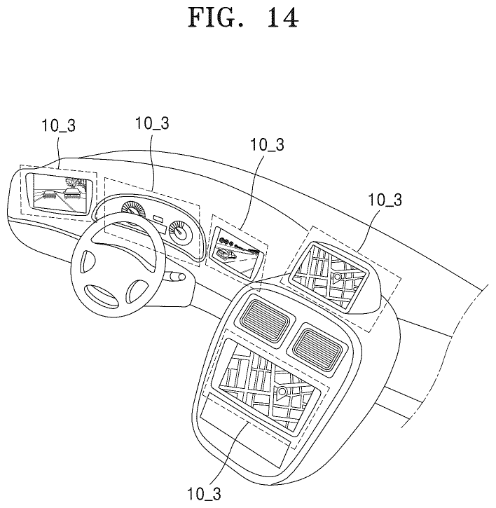

FIG. 14 illustrates an example in which an electronic device including a display panel is applied to a vehicle. For example, an electronic device 10_3 may be applied to dashboards, center fascia, etc. of automobiles, or may be applied to center information displays (CIDs) on dashboards of automobiles or room mirror displays replacing side mirrors.

Although not illustrated, the electronic device to which the display device according to embodiments is applied may include screen display-oriented devices, such as billboards, electronic boards, or game consoles, and various home appliances that display information on display panels, such as refrigerators, washing machines, dryers, air conditioners, or robot vacuum cleaners. In addition, when the display panel has a function of transmitting light, the display panel may be applied to electronic devices, such as a smart window or a transparent display device that displays a background and a display image together. The types of electronic devices according to embodiments are not limited to those described above, and application of various other electronic devices not described herein may also be possible.

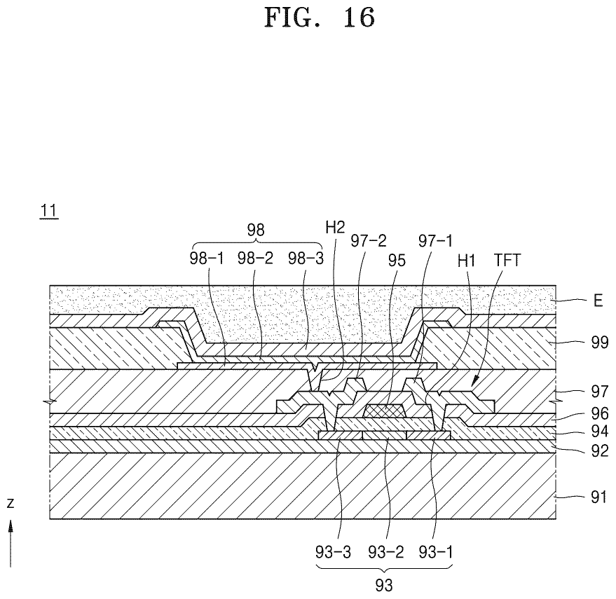

FIG. 15 is a schematic plan view of an electronic device according to an embodiment. FIG. 16 is a cross-sectional view of a display panel according to an embodiment.

FIG. 15 illustrates an embodiment in which the electronic device 10 is a smartphone, but the disclosure is not necessarily limited thereto. The electronic device 10 may include a display panel 11 and a housing 19. In an embodiment, the display panel 11 may be accommodated in the housing 19. The housing 19 is not necessarily implemented in the form illustrated in FIG. 15, and any housing may belong to the housing 19 of the disclosure without limitations in types or shapes as long as the housing provides a space in which the display panel 11 may be accommodated.

Referring to FIGS. 15 and 16, a display area DA and a peripheral area PA outside the display area DA may be defined on a substrate 91 of the display panel 11. A light-emitting element 98 may be disposed in the display area DA, and a power line (not shown) or the like may be disposed in the peripheral area PA.

A plurality of deposition material patterns may be disposed in the display area DA. Although FIG. 15 illustrates that the display panel 11 and the display area DA are approximately rectangular, the disclosure is not necessarily limited thereto. The display panel 11 and/or the display area DA may have other shapes, for example, an irregular shape.

The display panel 11 may include the substrate 91, a thin-film transistor TFT on the substrate 91, and the light-emitting element 98 on the thin-film transistor TFT. The light-emitting element 98 may be electrically connected to the thin-film transistor TFT.

The substrate 91 may include a plastic material or may include a metal material. In an embodiment, the substrate 91 may include polyimide (PI). The thin-film transistor TFT may be disposed on the substrate 91, a via-layer 97 may be disposed to cover the thin-film transistor TFT, and the light-emitting element 98 may be disposed on the via-layer 97.

A buffer layer 92 including an inorganic insulating material may be further disposed on the upper surface of the substrate 91. The buffer layer 92 may include silicon oxide (SiO₂), silicon nitride (SiNₓ), and/or silicon oxynitride (SiON).

An active layer 93 may be disposed on the buffer layer 92 in a certain pattern, and the active layer 93 may be covered by a gate insulating layer 94. The active layer 93 may have a source region 93-1 and a drain region 93-3 and may have a channel region 93-2 between the source region 93-1 and the drain region 93-3.

The active layer 93 may be formed to include various materials. In an embodiment, the active layer 93 may include an inorganic semiconductor material, such as amorphous silicon or crystalline silicon. In an embodiment, the active layer 93 may include an oxide semiconductor. In an embodiment, the active layer 93 may include an organic semiconductor material.

The active layer 93 may be formed by forming an amorphous silicon layer on the buffer layer 92, crystallizing the amorphous silicon layer to form a polycrystalline silicon layer, and then patterning the polycrystalline silicon layer. In an embodiment, the apparatus 20 for manufacturing a display panel (see FIG. 1A) may be used when crystallizing the amorphous silicon layer to form the polycrystalline silicon layer. In this case, the apparatus 20 for manufacturing a display panel may be used as a laser annealing apparatus. The active layer 93 may have the source region 93-1 and the drain region 93-3 doped with impurities.

A gate electrode 95 corresponding to the active layer 93 and an interlayer-insulating layer 96 covering the gate electrode 95 may be disposed on the upper surface of the gate insulating layer 94. Contact holes H1 may be defined in the interlayer-insulating layer 96 and the gate insulating layer 94, and then, a source electrode 97-1 and a drain electrode 97-2 may be disposed on the interlayer-insulating layer 96 to make contact with the source region 93-1 and the drain region 93-3, respectively.

The via-layer 97 may be disposed on the thin-film transistor TFT, and a pixel electrode 98-1 of the light-emitting element 98 may be disposed on the via-layer 97. The pixel electrode 98-1 may be in contact with the drain electrode 97-2 of the thin-film transistor TFT through a via-hole H2 defined in the via-layer 97. The via-layer 97 may include one or more layers including an inorganic material and/or an organic material, may be formed as a planarization layer so that the upper surface thereof is flat regardless of the curvature of the lower layer, or may be formed to be curved along the curvature of the layer disposed therebelow.

After the pixel electrode 98-1 is disposed on the via-layer 97, a pixel defining layer 99 may be formed to cover the pixel electrode 98-1 and the via-layer 97, and the pixel defining layer 99 may be opened so that a portion of the pixel electrode 98-1 is exposed.

An intermediate layer 98-2 and an opposite electrode 98-3 may be disposed on the pixel electrode 98-1. The opposite electrode 98-3 may be disposed on the intermediate layer 98-2 and the pixel defining layer 99. In an embodiment, the opposite electrode 98-3 may be disposed on the entirety of the substrate 91.

The intermediate layer 98-2 may include an emission layer. As another optional example, the intermediate layer 98-2 may include an emission layer and may further include at least one of a hole injection layer, a hole transport layer, an electron transport layer, or an electron injection layer. However, the disclosure is not limited thereto, and the intermediate layer 98-2 may include an emission layer and may further include various other functional layers (not shown).

The pixel electrode 98-1 and the opposite electrode 98-3 may be insulated from each other by the intermediate layer 98-2. Voltages of different polarities are applied to the intermediate layer 98-2 by the pixel electrode 98-1 and the opposite electrode 98-3 so that light emission may occur in the emission layer included in the intermediate layer 98-2.

A plurality of intermediate layers 98-2 may be provided. The plurality of intermediate layers 98-2 may form the display area DA. In this case, the plurality of intermediate layers 98-2 may be spaced apart from each other in the display area DA.

A thin-film encapsulation layer E may include a plurality of inorganic layers or may include an inorganic layer and an organic layer. The organic layer of the thin-film encapsulation layer E may include polymer. Specifically, the organic layer of the thin-film encapsulation layer E may be a single layer or a stacked layer including one of polyethylene terephthalate, polyimide, polycarbonate, epoxy, polyethylene, and polyacrylate. The inorganic layer of the thin-film encapsulation layer E may be a single layer or a stacked layer including a metal oxide or a metal nitride. For example, the inorganic layer may include one of silicon oxide (SiO₂), silicon nitride (SiNₓ), silicon oxynitride (SiON), aluminum oxide (Al₂O₃), and titanium oxide (TiO₂). The uppermost layer of the thin-film encapsulation layer E, exposed to the outside, may include an inorganic layer so as to prevent moisture from penetrating the light-emitting element.

The thin-film encapsulation layer E may include at least one sandwich structure in which at least one organic layer is inserted between at least two inorganic layers. As another example, the thin-film encapsulation layer E may include at least one sandwich structure in which at least one inorganic layer is inserted between at least two organic layers. As another example, the thin-film encapsulation layer E may include a sandwich structure in which at least one organic layer is inserted between at least two inorganic layers and a sandwich structure in which at least one inorganic layer is inserted between at least two organic layers.

According to an embodiment, an apparatus for manufacturing a display panel is provided which is capable of recycling a laser by emitting a laser reflected from a first area (e.g., a main processing area) to a second area (e.g., an auxiliary processing area) and emitting a laser reflected from the second area back to the first area. This may reduce the amount of energy required in the process of manufacturing a display panel (e.g., in a laser processing process) and improve the efficiency of the laser processing process.

The disclosure may also provide a method of manufacturing a display panel having the above-described features. The disclosure may also provide an electronic device including a display panel having the above-described features. The disclosure may also provide a method of manufacturing an electronic device, including a method of manufacturing a display panel having the above-described features.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. An apparatus for manufacturing a display panel, the apparatus comprising:
a light source;
a first optical member, which causes light emitted from the light source to be incident on a first area; and
a second optical member, which causes light reflected from the first area to be incident on a second area,
wherein the apparatus is configured to cause light reflected from the second area to be incident back on the first area.

2. The apparatus of claim 1, wherein the first optical member comprises at least one of a mirror or a lens.

3. The apparatus of claim 2, wherein the first optical member comprises the mirror and the lens, and the lens is disposed between the mirror and the first area.

4. The apparatus of claim 1, wherein the second optical member comprises a mirror.

5. The apparatus of claim 1, wherein the second optical member causes the light reflected from the second area to be incident back on the first area.

6. The apparatus of claim 5, wherein a path of the light incident on the second area by the second optical member and a path of the light reflected from the second area coincide with each other, while a traveling direction of the light incident on the second area by the second optical member and a traveling direction of the light reflected from the second area are opposite to each other.

7. The apparatus of claim 5, wherein a path of the light reflected from the first area and a path of the light incident back on the first area by the second optical member coincide with each other, while a traveling direction of the light reflected from the first area and a traveling direction of the light incident back on the first area by the second optical member are opposite to each other.

8. The apparatus of claim 1, further comprising a third optical member, which causes the light reflected from the second area to be incident on the first area.

9. The apparatus of claim 8, wherein the second optical member is integrally provided with the third optical member.

10. The apparatus of claim 1, further comprising a fourth optical member disposed on a path of the light incident on the second area.

11. The apparatus of claim 10, wherein the fourth optical member comprises a lens.

12. A method of manufacturing a display panel, the method comprising:
causing light emitted from a light source to be incident on a first area;
causing light reflected from the first area to be incident on a second area; and
causing light reflected from the second area to be incident back on the first area.

13. The method of claim 12, wherein the causing of the light emitted from the light source to be incident on the first area comprises at least one of adjusting a path of light emitted from a light source by using a mirror, or focusing the light by using a lens.

14. The method of claim 12, wherein the causing of the light reflected from the first area to be incident on the second area comprises adjusting a path of the light reflected from the first area by using a mirror.

15. The method of claim 12, wherein the causing of the light reflected from the first area to be incident on the second area and the causing of the light reflected from the second area to be incident back on the first area are performed by a same optical member.

16. The method of claim 15, wherein a path of the light incident on the second area and a path of the light reflected from the second area coincide with each other.

17. The method of claim 12, further comprising focusing the light incident on the second area.

18. The method of claim 12, wherein the method comprises laser annealing or laser peeling.

19. A method of manufacturing an electronic device, the method comprising:
manufacturing a display panel; and
coupling the manufactured display panel to a housing,
wherein the manufacturing of the display panel comprises:
causing light emitted from a light source to be incident on a first area;
causing light reflected from the first area to be incident on a second area; and
causing light reflected from the second area to be incident back on the first area.

20. The method of claim 19, wherein the manufacturing of the display panel comprises laser annealing or laser peeling.
